(19) United States
(12) Patent Application Publication
(10) Pub. No.: US 2026/0371482 A1
(43) Pub. Date: Nov. 19, 2026

(54) COMPOSITION AND METHOD OF MANUFACTURING OF THIN PLOYMER DIELECTRIC SUBSTRATES WITH LOW DIELECTRIC LOSSES AT ULTRAHIGH FREQUENCIES, FOILED WITH AN ELECTRICALLY CONDUCTIVE LAYER ON ONE OR TWO SIDES

(71) Applicants: SINTEZ-PROEKT LIMITED LIABILITY COMPANY, Moscow (RU); LG ELECTRONICS INC., Seoul (KR)

(72) Inventors: Vasilii Fedorovich ARISTOV, Pereslavl-Zalesskiy (RU); Ilya Aleksandrovich VIKHROV, Pereslavl-Zalesskiy (RU); Dongjoo YOU, Seoul (KR); Seongmoon CHO, Seoul (KR)

(73) Assignees: SINTEZ-PROEKT LIMITED LIABILITY COMPANY, Moscow (RU); LG ELECTRONICS INC., Seoul (KR)

(21) Appl. No.: 19/489,221

(22) PCT Filed: Jun. 1, 2023
(86) PCT No.: PCT/RU2023/000158

§ 371 Date: Jul. 31, 2026

(51) Int. Cl. H05K 1/03; H05K 3/20

(52) U.S. Cl. CPC H05K 1/0373; H05K 3/202; H05K 2201/015; H05K 2201/0158; H05K 2201/0209; H05K 2203/065

(57) ABSTRACT

A composition and a method of manufacturing of thin (150 μm and thinner) polymer dielectric substrates with low dielectric losses (less than 0.001) at ultrahigh frequencies (5G, 6G generations), foiled with an electrically conductive layer on one or two sides. The composition of the polymer substrate consists of fluoroplastic, processed by injection molding, and a quartz filler. The fluoroplastic is from a number of copolymers of perfluorinated ethylene and propylene grades F-4MB or analogues: Teflon FEP, Neoflon FEP, Dyneon FEP. The quartz filler may consist of continuous fibers (bundles or threads, fabrics) and/or dispersed fillers (discrete fibers, powders, flakes, etc.). The technology for producing a foiled dielectric implies the absence of a special adhesive layer between the foil and the polymer substrate and consists in hot pressing of three separate components—a polymer film, a quartz filler and a foil, that is the filler is impregnated with a melt of fluoroplastic and the dielectric material is attached to the metal foil in one step.

### TECHNICAL FIELD

The invention relates to the field of radio engineering and electronic industry, namely to the technology of manufacturing dielectric substrates for printed circuit boards.

### BACKGROUND ART

For printed circuit boards of chips operating at frequencies above 20 GHz (5G, 6G), it is preferable to use materials with minimal dielectric losses (not more than 0.001) and a minimum dielectric constant (not more than 2.5) as dielectric materials. Such materials can be ceramic materials (not considered in this application, because they belong to a different class of materials and have a much narrower scope and higher cost) and polymeric materials.

Many polymer materials traditionally used in printed circuit boards at frequencies below 10-20 GHz have too high dielectric losses at frequencies above 20 GHz (more than 0.001). For use in the frequency range above 20 GHz, polymeric materials from the range of polyolefins and fluorinated polyolefins remain suitable. At the same time, polyolefins do not meet the requirements of heat resistance, so the only class of polymers suitable for the above tasks are fluorine-containing polyolefins.

Most of the existing polymer dielectric substrates of printed circuit boards are made on the basis of polytetrafluoroethylene (hereinafter referred to as PTFE), because this polymer has low dielectric losses (less than 0.001) in the widest frequency range, has excellent chemical resistance and heat resistance. Among the disadvantages, firstly, it can be noted that PTFE has too high a coefficient of linear thermal expansion of CTE, therefore, to obtain dielectric substrates of printed circuit boards, it is filled with continuous or dispersed ceramic fillers, most often based on glass materials. However, for use in the frequency range above 20 GHz, filling fluoropolymers with such ceramic materials or glass materials is not permissible, because it leads to an increase (more than 0.001) of dielectric loss Df. The second significant disadvantage of PTFE in terms of applicability to the manufacture of foiled dielectrics is the extremely low adhesion to most adhesives, which requires complex and expensive preparation of the PTFE surface before bonding, for example, treatment with melts of alkali metals or their complexes.

### DISCLOSURE

### Technical Problem

The closest analogue to the present invention is the international application for invention EP 0 695 116 A1 by Rogers Corporation's, where the composite material described in the application includes at least two types of ceramic fillers in order to be able to independently adjust the dielectric constant Dk (ranging from 3 to 20) and CTE of the composite. However, this application did not pursue the goal of obtaining a material with a dielectric loss of Df less than 0.001 at frequencies above 20 GHz (5G, 6G communication generations). Therefore, in all examples of the invention, a glass cloth or non-woven fabric is used to reduce CTE, or a very high (~60%) filling of the dielectric material with a dispersed filler with fused amorphous silicon dioxide, which leads to a high (2.9 or more) value of Dk. As a matrix, the most preferred is Polytetrafluoroethylene (PTFE), but it may also contain one or a combination of the following fluoropolymers: tetrafluoroethylene-perfluoroalkyl vinyl ether copolymer (PFA), hexafluoropropylene-tetrafluoroethylene copolymer (FEP), ethylene-tetrafluoroethylene copolymer and polyvinylidene fluoride.

### Technical Solution

The claimed composition and technology of the present invention are devoid of these disadvantages and make it possible to obtain a material with minimal dielectric losses (not more than 0.001) and a minimum dielectric constant (not more than 2.5) at frequencies including those above 20 GHz. The present invention is as follows: to obtain a foiled dielectric as a polymer material, films based on fusible copolymers of perfluorinated ethylene and propylene, quartz fillers and metal foils are used, while the finished material is obtained in one step by hot pressing without the use of additional adhesives and does not require pre-treatment of the polymer film, quartz filler and foil. Impregnation of the filler and adhesion to the foil are provided by increased pressure and temperature in the range from 290 to 330 °C. Copolymers of hexafluoropropylene and tetrafluoroethylene (FEP) were chosen as a fluoropolymer matrix, since in comparison with polytetrafluoroethylene (PTFE): 1) a lower processing temperature is required (lower energy consumption, auxiliary equipment and heat-pressing equipment are cheaper) and 2) lower viscosity of the melt allows more efficient impregnation of reinforcing fillers.

### Advantageous Effects

The present invention makes it possible to obtain foiled dielectrics with a dielectric material thickness of at least 50 to 150 μm and above, with a dielectric constant below 2.5 and a dielectric loss tangent of less than 0.001, incl. at frequencies from 20 to 200 GHz. In addition, the resulting materials have low CTE values in the XY plane due to quartz fillers. The invention is illustrated by the following examples.

### MODE FOR INVENTION

### Example 1. Foiled Dielectric Based on Quartz Filaments and F-4MB Film

Copper foil with a thickness of 18 μm was placed on the forming flat tooling, then a film of F-4MB with a thickness of 50 μm, then the quartz thread was wound first in the X direction in increments of 1 mm, then in the perpendicular direction Y in increments of 0.5 mm (equivalent to two passes with a step of 1 mm) and again in the X direction in increments of 1 mm. The assembly was placed in a plane-parallel mold and heated under pressure from 1 t to 10 t up to a temperature of 300 °C, cooled down to room temperature, unloaded, and the foiled dielectric was removed from the mold. The resulting material had the following characteristics: Dk/Df=2.61/0.00086 at 28 GHz, 2.59/0.00063 at 60 GHz, the adhesion of the copper foil to the dielectric substrate was 2.81 N/mm when peeling at an angle of 90°, CTE in the temperature range from 30 to 150 °C in the direction of X and Y=10.9×10⁻⁶ K⁻¹, the thickness of the dielectric layer was 150 μm.

### Example 2. Foiled Dielectric Based on Quartz Non-Woven Fabric and Teflon FEP Film

Copper foil with a thickness of 18 μm, then Teflon FEP film with a thickness of 35 μm, then a quartz veil of 10 g/m² with a thickness of 50 μm, bound with a polyimide composition, and again copper foil with a thickness of 18 μm, were placed on the forming flat tooling. The assembly was placed in a plane-parallel mold and heated under pressure from 1 t to 10 t up to a temperature of 310 °C, cooled down to room temperature, unloaded, and the foiled dielectric was removed from the mold. The resulting material had the following characteristics: Dk/Df=2.02/0.00064 at 28 GHz, 2.00/0.00059 at 60 GHz, the adhesion of copper foil to the dielectric substrate was 1.83 N/mm when peeling at an angle of 90°, CTE in the temperature range from 30 to 150 °C in the direction of X and Y=26.7×10⁻⁶ K⁻¹, the thickness of the dielectric layer was 64 μm.

### Example 3. Foiled Dielectric Based on Quartz Non-Woven Fabric and F-4MB Film

Copper foil with a thickness of 18 microns, then F-4MB film with a thickness of 35 microns, then a quartz veil of 8 g/m² with a thickness of 50 microns, bound with an epoxy composition, and again copper foil with a thickness of 35 microns were placed on the forming flat tooling. The assembly was placed in a plane-parallel mold and heated under pressure from 1 t to 10 t up to a temperature of 310 °C, cooled down to room temperature, unloaded, and the foiled dielectric was removed from the mold. The resulting material had the following characteristics: Dk/Df=2.05/0.00070 at 28 GHz, 2.03/0.00062 at 60 GHz, the adhesion of copper foil to the dielectric substrate was 1.51 N/mm when peeling at an angle of 90°, CTE in the temperature range from 30 to 150 °C in the direction of X and Y=30.5×10⁻⁶ K⁻¹, the thickness of the dielectric layer was 60 μm.

### Example 4. Foiled Dielectric Based on Quartz Filaments and Neoflon FEP film

Copper foil with a thickness of 18 μm was placed on the forming flat tooling, then Neoflon FEP film with a thickness of 50 μm, then the quartz filament was wound first in the X direction in increments of 2 mm, then in the perpendicular direction Y in increments of 1 mm (equivalent to two passes in increments of 2 mm) and again in the X direction in increments of 2 mm. The assembly was placed in a plane-parallel mold and heated under pressure from 1 t to 10 t up to a temperature of 300 °C, cooled down to room temperature, unloaded, and the foil dielectric was removed from the mold. The resulting material had the following characteristics: Dk/Df=2.20/0.00065 at 28 GHz, 2.20/0.00062 at 60 GHz, adhesion of copper foil to the dielectric substrate was 2.95 N/mm when peeling at an angle of 90°, CTE in the temperature range from 30 to 150 °C in the direction of X and Y=17.0×10⁻⁶ K⁻¹, the thickness of the dielectric layer was 125 μm.

1. Composition for the manufacture of polymer dielectric substrates with dielectric losses of less than 0.001 at ultrahigh frequencies, including generations 5G, 6G, consisting of a polymer material of copolymers of perfluorinated ethylene and propylene with a quartz filler in the form of continuous fibers and/or dispersed particles.

2. A method for producing foiled dielectrics without a special adhesive layer between the foil and the dielectric substrate, carried out by hot pressing polymer films, quartz fillers and foil together at once.
